(19) United States
(12) Patent Application Publication
(10) Pub. No.: US 2026/0349350 A1
(43) Pub. Date: Nov. 5, 2026

(54) SIMULATING AN ELECTROMAGNETIC RESPONSE OF A SEMICONDUCTOR STRUCTURE FOR DIFFRACTION BASED OPTICAL METROLOGY

(71) Applicant: ASML NETHERLANDS B.V., Veldhoven (NL)

(72) Inventors: Shufeng BAI, Cupertino, CA (US); Jian WU, San Jose, CA (US); Frank Jaco BUIJNSTERS, Eindhoven (NL); David Harold WHYSONG, Dublin, CA (US)

(73) Assignee: ASML NETHERLANDS B.V., Veldhoven (NL)

(21) Appl. No.: 19/125,401

(22) PCT Filed: Nov. 8, 2023
(86) PCT No.: PCT/EP2023/081103

§ 371 Date: Apr. 29, 2025

Related U.S. Application Data
(60) Provisional application No. 63/425,235, filed on Nov. 14, 2022.

(51) Int. Cl. G03F 7/00

(52) U.S. Cl. CPC G03F 7/70504; G03F 7/70633; G03F 7/70683

(57) ABSTRACT

Simulating an electromagnetic response of a semiconductor structure for diffraction based optical metrology. The simulated electromagnetic response is used to determine an optical property of the semiconductor structure, such as a reflectivity coefficient. A rigorous coupled wave analysis (RCWA) is used to simulate reflectivity of the semiconductor structure layer by layer, and unit cell by unit cell. With a proper choice of a division point, the semiconductor structure can be separated into top and bottom portions that can be further sub-divided into smaller, identical unit cells in an X-Y plane. These unit cells can be simulated individually, and then the simulations can be combined to obtain the reflection coefficient of the entire semiconductor structure. This RCWA+unit cell simulation approach may decrease required simulation time, may not require calculation of a full scattering matrix, and/or has one or more other advantages compared to prior approaches.

### CROSS-REFERENCE TO RELATED APPLICATIONS

This application claims priority of U.S. application 63/425,235 which was filed on 14 Nov. 2022, and which is incorporated herein in its entirety by reference.

### TECHNICAL FIELD

The present disclosure relates to simulating an electromagnetic response of a semiconductor structure for diffraction based optical metrology.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) at a patterning device (e.g., a mask) onto a layer of radiation-sensitive material (resist) provided on a substrate (e.g., a wafer).

To project a pattern on a substrate a lithographic apparatus may use electromagnetic radiation. The wavelength of this radiation determines the minimum size of features which can be formed on the substrate. Typical wavelengths currently in use are 365 nm (i-line), 248 nm, 193 nm and 13.5 nm. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

Low-k1 lithography may be used to process features with dimensions smaller than the classical resolution limit of a lithographic apparatus. In such a process, the resolution formula may be expressed as CD=k1ₓ X/NA, where X is the wavelength of radiation employed, NA is the numerical aperture of the projection optics in the lithographic apparatus, CD is the “critical dimension” (generally the smallest feature size printed, but in this case half-pitch) and ki is an empirical resolution factor. In general, the smaller k1 the more difficult it becomes to reproduce the pattern on the substrate that resembles the shape and dimensions planned by a circuit designer in order to achieve particular electrical functionality and performance. To overcome these difficulties, sophisticated fine-tuning steps may be applied to the lithographic projection apparatus and/or design layout. These include, for example, but not limited to, optimization of NA, customized illumination schemes, use of phase shifting patterning devices, various optimization of the design layout such as optical proximity correction (OPC, sometimes also referred to as “optical and process correction”) in the design layout, or other methods generally defined as “resolution enhancement techniques” (RET). Alternatively, tight control loops for controlling a stability of the lithographic apparatus may be used to improve reproduction of the pattern at low k1.

Semiconductor-based devices may be produced by fabricating a series of layers on a substrate (e.g., a wafer), some or all of the layers including various structures. The relative position of these structures within a single layer and with respect to structures in other layers plays a key role in the performance of the devices. Overlay error relates to the misalignment between various structures. Overlay accuracy generally pertains to the determination of how accurately a first patterned layer aligns with respect to a second patterned layer disposed above or below it and to the determination of how accurately a first pattern aligns with respect to a second pattern disposed on the same layer. Overlay measurements are performed via metrology targets that are printed together with layers of the wafer. Images of the metrology targets are captured via an imaging tool and are analyzed to determine both X-overlay and Y-overlay measurements.

Known techniques exist to simulate an electromagnetic response of a metrology target in software before fabricating them onto a substrate. This simulation enables a designer to determine one or more parameters associated with the electromagnetic response of the metrology target and make changes to the design of the metrology target to optimize the one or more parameters.

### SUMMARY

Simulating an electromagnetic response of a semiconductor structure, such as a metrology target, for diffraction based optical metrology is described. Known techniques for simulating an electromagnetic response of a metrology target are typically applied to metrology targets comprising a multi-layer structure such as a grating, wherein grating lines have the same pitch. This involves rigorously simulating the electromagnetic response of the metrology target using Maxwell solvers, e.g. using Rigorous Coupled-Wave Analysis (RCWA), for various parameters of light incident on the metrology target and for different critical dimensions (CD) and pitches of the metrology target. However, when the grating lines of the upper grating and the lower grating are not equal, i.e. have different pitches, the computational complexity of the simulation increases such that using known Maxwell solving techniques take a much greater length of time, making the use of known Maxwell solving techniques for such a metrology target design impractical or sometimes even impossible.

A new approach for using an RCWA to simulate reflectivity of the semiconductor structure layer by layer, unit cell by unit cell, and determine an optical property such as a reflection coefficient for the semiconductor structure, is described. With a proper choice of a division point (e.g., a mid-point), the semiconductor structure can be separated into first (e.g., top) and second (e.g., bottom) portions that can be further sub-divided into smaller, identical unit cells in an X-Y plane. These unit cells can be simulated individually, and then the simulations can be combined together to obtain the reflection coefficient of the entire semiconductor structure. The presently disclosed RCWA applied in a unit cell simulation approach advantageously decreases required simulation time, does not require calculation of a full scattering matrix, and has other advantages compared to prior approaches.

According to an embodiment, there is provided a method for simulating an electromagnetic response of a semiconductor structure to determine an optical property of the semiconductor structure for diffraction based optical metrology. The method comprises separating an electronic representation of the semiconductor structure into first and second portions. The method comprises separately simulating an electromagnetic response of the first portion and the second portion using a layer based simulation. The method comprises combining separate simulations of the electromagnetic response of the first portion and the second portion into a combined simulation. Only partial (e.g., reflectivity) portions of scattering matrices determined by the layer based simulation for the separate simulations are combined for the combined simulation of the electromagnetic response such that the combined simulation comprises only the partial portions. The method comprises determining the optical property based on the combined simulation of the electromagnetic response.

In some embodiments, the partial portions of scattering matrices comprise reflectivity portions and/or other portions.

In some embodiments, the layer based simulation comprises or is based on rigorous coupled wave analysis (RCWA), and the separate simulations are performed layer by layer, from top to bottom, bottom to top, or from outer layers to inner layers of the first and second portions of the semiconductor structure.

In some embodiments, the optical property comprises a transmissive and/or reflective property of the semiconductor structure in response to incident radiation.

In some embodiments, the optical property comprises a reflection coefficient.

In some embodiments, the first portion has first repeating structures, and the second portion has second, different repeating structures.

In some embodiments, the first and second repeating structures are in an X and/or a Y direction of the semiconductor structure, the first portion is a top portion of the semiconductor structure, and the second portion is a bottom portion of the semiconductor structure.

In some embodiments, the method further comprises separating the first portion into first repeating unit cells based on the first repeating structures, separating the second portion into second repeating unit cells based on the second repeating structures, separately simulating an electromagnetic response of each of the first and second repeating unit cells using the layer based simulation combining separate simulations of the first repeating unit cells to generate an intermediate result (e.g., an intermediate simulation) for the first portion; and combining separate simulations of the second repeating unit cells to generate an intermediate result (e.g., another intermediate simulation) for the second portion.

In some embodiments, separately simulating the electromagnetic response of each of the first and second repeating unit cells using the layer based simulation comprises performing a rigorous coupled wave analysis for each given unit cell.

In some embodiments, combining the separate simulations of the first repeating unit cells to generate the simulation of the first portion comprises determining a first layer based intermediate scattering matrix, and combining the separate simulations of the second repeating unit cells to generate the simulation of the second portion comprises determining a second layer based intermediate scattering matrix.

In some embodiments, the first and second layer based intermediate scattering matrices comprise a top down reflectivity matrix and a bottom up reflectivity matrix, respectively.

In some embodiments, the first and second layer based intermediate scattering matrices are different.

In some embodiments, combining the separate simulations of the first portion and the second portion into a combined simulation comprises a rigorous coupled wave analysis step based on the first and second layer based intermediate scattering matrices.

In some embodiments, the rigorous coupled wave analysis based on the first and second layer based intermediate scattering matrices comprises a matrix transformation.

In some embodiments, the electronic representation of the semiconductor structure is determined based on a design layout of a semiconductor device.

In some embodiments, the semiconductor structure comprises a semiconductor metrology target for diffraction based optical metrology.

In some embodiments, the metrology target comprises a grating.

In some embodiments, the optical property is configured to be provided as input for an overlay and/or alignment simulation as part of a semiconductor manufacturing process.

In some embodiments, the method further comprises determining a semiconductor structure metrology target design based on the combined simulation and/or the determined optical property.

In some embodiments, there is provided a non-transitory computer readable medium having instructions thereon, the instructions when executed by a computer causing the computer to perform one or more of the operations of the method described above.

In some embodiments, there is provided a system comprising one or more processors configured by machine readable instructions to perform one or more of the operations of the method described above.

Other advantages of the embodiments of the present disclosure will become apparent from the following description taken in conjunction with the accompanying drawings, which set forth, by way of illustration and example, certain example embodiments.

### BRIEF DESCRIPTION OF THE DRAWINGS

The accompanying drawings, which are incorporated in and constitute a part of the specification, illustrate one or more embodiments and, together with the description, explain these embodiments. Embodiments will now be described, by way of example only, with reference to the accompanying schematic drawings in which corresponding reference symbols indicate corresponding parts, and in which:

FIG. 1 is a schematic diagram of a lithographic projection apparatus, according to an embodiment.

FIG. 2 depicts a schematic overview of a lithographic cell, according to an embodiment.

FIG. 3 depicts a schematic representation of holistic lithography, representing a cooperation between three technologies to optimize semiconductor manufacturing, according to an embodiment.

FIG. 4 illustrates an exemplary computer implemented method for simulating an electromagnetic response of a semiconductor structure to determine an optical property of the semiconductor structure for diffraction based optical metrology, according to an embodiment.

FIG. 5 provides a graphical representation of the exemplary method for simulating an electromagnetic response of a semiconductor structure to determine an optical property of the semiconductor structure for diffraction based optical metrology, according to an embodiment.

FIG. 6 is a diagram of an example computer system that may be used for one or more of the operations described herein, according to an embodiment.

### DETAILED DESCRIPTION

There are known methods for simulating an electromagnetic response and/or other optical properties of semiconductor structures for diffraction based optical metrology. These methods may include rigorous coupled wave analysis (RCWA). However, a run time complexity of RCWA scales cubically with a semiconductor structure area (or cell) used for a simulation. With the development of continuously biased diffraction based overlay (cDBO) metrology target structures, computing resources required for RCWA based simulations and simulation run times increased several fold, due to larger areas of a semiconductor structure that are required to be used for simulation, for example. More information about cDBO metrology target structures can be found in U.S. Pat. No. 10,996,570, which is incorporated by reference in its entirety.

Although a cell (e.g., a set of repeating structures in a target design) size of a cDBO target is typically larger than cell sizes of prior targets, a cDBO target cell can be separated into smaller cells. Therefore, a scattering matrix of the larger cell is still relatively sparse, and the sparsity can be used to speed simulations. However, this approach requires simulating a full scattering matrix of top and bottom portions of a metrology target structure separately, which still requires significant computing resources and simulation time.

A new approach for using RCWA to simulate reflectivity of the semiconductor structure layer by layer, unit cell by unit cell, and determine an optical property such as a reflection coefficient for the semiconductor structure, is described. With a proper choice of a division point (e.g., a mid-point), the semiconductor structure can be separated into first (e.g., top) and second (e.g., bottom) portions that can be further sub-divided into smaller, identical unit cells in an X-Y plane. These unit cells can be simulated individually, and then the simulations can be combined together to obtain the reflection coefficient of the entire semiconductor structure. This approach decreases required computational resources and/or simulation time, does not require calculation of a full scattering matrix, and/or has other advantages compared to prior approaches.

For example, unlike prior methods, the present approach does not require calculation of a full scattering matrix in every layer of a structure. Combining indeterminate results (e.g., intermediate simulations) from first and second portions of a structure is simplified relative to prior methods because, as described below, only portions of a combination related to a reflection coefficient calculation are needed. An expensive direct implementation of the Redheffer product is thus avoided in the present approach. This results in several folds of reduction in calculation complexity and speed improvement. A dramatic speedup can be achieved for simulations with cDBO target like structures, for example.

Embodiments of the present disclosure are described in detail with reference to the drawings, which are provided as illustrative examples of the disclosure so as to enable those skilled in the art to practice the disclosure. The figures and examples below are not meant to limit the scope of the present disclosure to a single embodiment, but other embodiments are possible by way of interchange of some or all of the described or illustrated elements. Where certain elements of the present disclosure can be partially or fully implemented using known components, only those portions of such known components that are necessary for an understanding of the present disclosure will be described, and detailed descriptions of other portions of such known components will be omitted so as not to obscure the disclosure. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. The present disclosure encompasses present and future known equivalents to the known components referred to herein by way of illustration.

Although specific reference may be made in this text to the manufacture of ICs, it should be explicitly understood that the description herein has many other applications. For example, it may be employed in the manufacture of integrated optical systems, guidance and detection patterns for magnetic domain memories, liquidcrystal display (LCD) panels, thinfilm magnetic heads, etc. The skilled artisan will appreciate that, in the context of such alternative applications, any use of the terms “reticle,” “wafer” or “die” in this text should be considered as interchangeable with the more general terms “mask,” “substrate,” and “target,” respectively.

In the present document, the terms “radiation” and “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 5-100 nm).

A (e.g., semiconductor) patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. The design rules may include or specify specific parameters, limits on ranges for parameters, or other information. One or more of the design rule limitations or parameters may be referred to as a “critical dimension” (CD). A critical dimension of a device can be defined as the smallest width of a line or hole or the smallest space between two lines or two holes, or other features. Thus, the CD determines the overall size and density of the designed device. One of the goals in device fabrication is to faithfully reproduce the original design intent on the substrate (via the patterning device).

The term “mask” or “patterning device” as employed in this text may be broadly interpreted as referring to a generic semiconductor patterning device that can be used to endow an incoming radiation beam with a patterned cross-section, corresponding to a pattern that is to be created in a target portion of the substrate. Besides the classic mask (transmissive or reflective; binary, phase-shifting, hybrid, etc.), examples of other such patterning devices include a programmable mirror array and a programmable LCD array.

As used herein, the term “patterning process” means a process that creates an etched substrate by the application of specified patterns of light as part of a lithography process. However, “patterning process” can also include (e.g., plasma) etching, as many of the features described herein can provide benefits to forming printed patterns using etch (e.g., plasma) processing.

As used herein, the term “pattern” means an idealized pattern that is to be etched on a substrate (e.g., wafer).

As used herein, a “printed pattern” (or a pattern on a substrate) means the physical pattern on a substrate that was etched based on a target pattern. The printed pattern can include, for example, troughs, channels, depressions, edges, or other two and three dimensional features resulting from a lithography process.

As used herein, the term “calibrating” means to modify (e.g., improve or tune) or validate something, such as a model.

A patterning system may be a system comprising any or all of the components described herein, plus other components configured to performing any or all of the operations associated with these components. A patterning system may include a lithographic projection apparatus, a scanner, systems configured to apply or remove resist, etching systems, or other systems, for example.

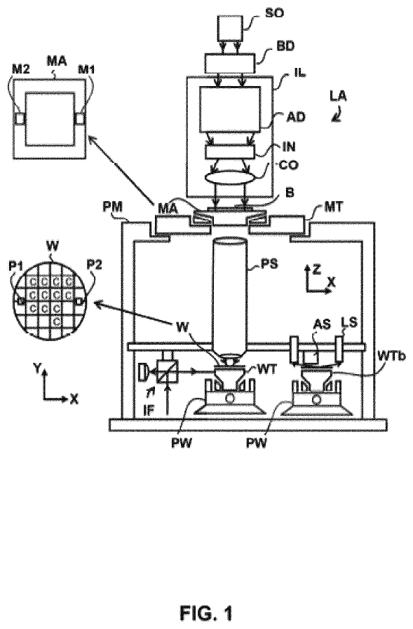

As an introduction, FIG. 1 is a schematic diagram of a lithographic projection apparatus LA, according to an embodiment. The lithographic projection apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, for example, so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

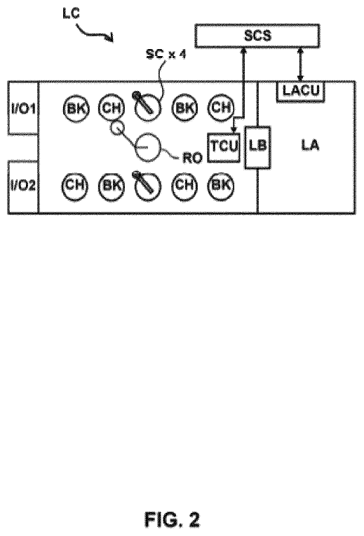

FIG. 2 depicts a schematic overview of a lithographic cell LC. As shown in FIG. 2, a lithographic projection apparatus (shown in FIG. 1 and illustrated as lithographic apparatus LA in FIG. 2) may form part of lithographic cell LC, also sometimes referred to as a lithocell or (litho)cluster, which often also includes apparatus to perform pre- and post-exposure processes on a substrate W (FIG. 1). Conventionally, these include spin coaters SC configured to deposit resist layers, developers to develop exposed resist, chill plates CH and bake plates BK, e.g., for conditioning the temperature of substrates W, e.g., for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g., via lithography control unit LACU.

In order for the substrates W (FIG. 1) exposed by the lithographic apparatus LA to be exposed correctly and consistently, it is desirable to inspect substrates to measure properties of patterned structures, such as feature edge placement, overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties using an actual substrate (e.g., a charged particle—SEM—image of a wafer pattern) or an image of an actual substrate, on a latent image (image in a resist layer after the exposure), on a semi-latent image (image in a resist layer after a post-exposure bake step PEB), on a developed resist image (in which the exposed or unexposed parts of the resist have been removed), on an etched image (after a pattern transfer step such as etching), or in other ways.

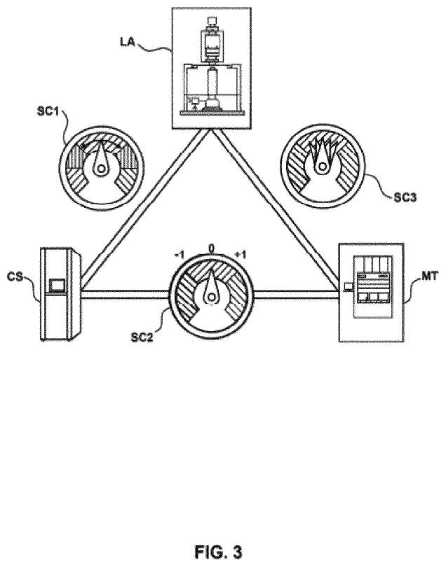

FIG. 3 depicts a schematic representation of holistic lithography, representing a cooperation between three technologies to optimize semiconductor manufacturing. Typically, the patterning process in lithographic apparatus LA is one of the most critical steps in the processing which requires high accuracy of dimensioning and placement of structures on the substrate W (FIG. 1). To ensure this high accuracy, three systems (in this example) may be combined in a so called “holistic” control environment as schematically depicted in Figure. 3. One of these systems is lithographic apparatus LA which is (virtually) connected to a metrology apparatus (e.g., a metrology tool) MT (a second system), and to a computer system CS (a third system). A “holistic” environment may be configured to optimize the cooperation between these three systems to enhance the overall process window and provide tight control loops to ensure that the patterning performed by the lithographic apparatus LA stays within a process window. The process window defines a range of process parameters (e.g., dose, focus, overlay) within which a specific manufacturing process yields a defined result (e.g., a functional semiconductor device)—typically within which the process parameters in the lithographic process or patterning process are allowed to vary.

The computer system CS may use (part of) a design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). Typically, the resolution enhancement techniques are arranged to match the patterning possibilities of the lithographic apparatus LA. The computer system CS may also be used to detect where within the process window the lithographic apparatus LA is currently operating (e.g., using input from the metrology tool MT) to predict whether defects may be present due to e.g., sub-optimal processing (depicted in FIG. 3 by the arrow pointing “0” in the second scale SC2).

The metrology apparatus (tool) MT may provide input to the computer system CS to enable accurate simulations and predictions, and may provide feedback to the lithographic apparatus LA to identify possible drifts, e.g., in a calibration status of the lithographic apparatus LA (depicted in FIG. 3 by the multiple arrows in the third scale SC3).

In lithographic processes, it is desirable to make frequent measurements of the structures created, e.g., for process control and verification. Tools to make such measurements include metrology tool (apparatus) MT. Different types of metrology tools MT for making such measurements are known, including scanning electron microscopes (SEM) or various forms of scatterometer metrology tools MT.

In some embodiments, metrology tools MT are or include a spectroscopic scatterometer, an ellipsometric scatterometer, or other light based tools. A spectroscopic scatterometer may be configured such that the radiation emitted by a radiation source is directed onto target features of a substrate and the reflected or scattered radiation from the target is directed to a spectrometer detector, which measures a spectrum (i.e., a measurement of intensity as a function of wavelength) of the specular reflected radiation. From this data, the structure or profile of the target giving rise to the detected spectrum may be reconstructed, e.g., by rigorous coupled wave analysis and non-linear regression or by comparison with a library of simulated spectra. An ellipsometric scatterometer allows for determining parameters of a lithographic process by measuring scattered radiation for each polarization states. Such a metrology tool (MT) emits polarized light (such as linear, circular, or elliptic) by using, for example, appropriate polarization filters in the illumination section of the metrology apparatus. A source suitable for the metrology apparatus may provide polarized radiation as well.

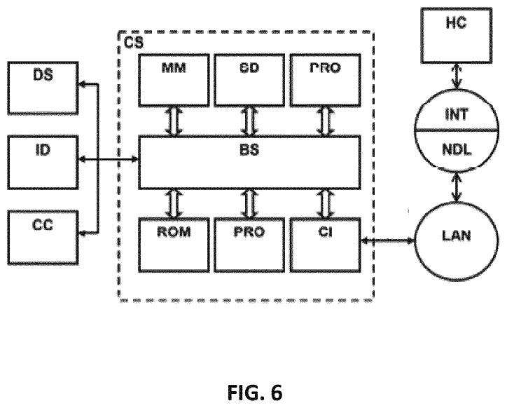

It is often desirable to be able to computationally determine how a patterning process would produce a desired pattern on a substrate. Thus, simulations may be provided to simulate one or more parts of the process. A metrology target on the substrate W (FIG. 1) is used to determine the alignment of different layers of the same substrate W. Embodiments of the present disclosure relate to the software simulation of an electromagnetic response of a candidate metrology target and/or other semiconductor structures as part of a design process for determining an optimal metrology target design that is to be manufactured on a substrate W. The simulation method described herein is performed on a computing device such as computing device CS shown in FIG. 3 (and again in FIG. 6 below).

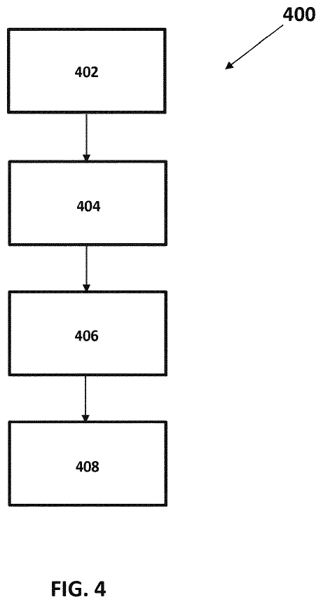

FIG. 4 illustrates an exemplary computer implemented method 400 for simulating an electromagnetic response of a semiconductor structure to determine an optical property of the semiconductor structure for diffraction based optical metrology. Simulation output can be used, for example, for optical metrology target design and/or for other purposes. An electronic representation of a semiconductor structure may be used for simulation. In some embodiments, the semiconductor structure comprises a semiconductor metrology target for diffraction based optical metrology. This may include a grating and/or other structures. The electronic representation of the semiconductor structure is determined based on a design layout of a semiconductor device, and/or other information. The electronic representation may be an electronic model generated based on a design layout and/or other information. This can be provided in a standardized digital file format such as GDSII, OASIS or another file format, for example.

Simulations with the model can be used to configure one or more features of the semiconductor structure (e.g., a metrology target design), one or more features of the illumination used for metrology (e.g., changing one or more characteristics of a spatial/angular intensity distribution of the illumination, such as change a shape), and/or other operations. Such configuration can be referred to as optimization.

In some embodiments, an optimization process may use or be based on a cost function. The optimization process may comprise finding a set of parameters (design variables, process variables, etc.) that minimizes the cost function. The cost function can have any suitable form depending on the goal of the optimization. For example, the cost function can be weighted root mean square (RMS) of deviations of certain characteristics (evaluation points) with respect to intended values (e.g., ideal values) of these characteristics. The cost function can also be the maximum of these deviations (i.e., worst deviation).

In some embodiments, method 400 is performed as part of a diffraction based optical metrology target design process (e.g., for an overlay and/or alignment target), for example. In some embodiments, one or more operations of method 400 may be implemented in or by computer system CS illustrated in FIG. 3 and/or FIG. 6 (below), and/or in or by other systems, for example. In some embodiments, method 400 comprises separating (operation 402) an electronic representation of a semiconductor structure such as a metrology target into first and second portions; separately simulating (operation 404) an electromagnetic response of the first portion and the second portion using a layer based simulation; combining (operation 406) separate simulations of the electromagnetic response of the first portion and the second portion into a combined simulation, where only partial (e.g., reflectivity) portions of scattering matrices determined by the layer based simulation for the separate simulations are combined for the combined simulation; determining (operation 408) an optical property based on the combined simulation; and/or other operations.

The operations of method 400 are intended to be illustrative. In some embodiments, method 400 may be accomplished with one or more additional operations not described, and/or without one or more of the operations discussed. For example, in some embodiments, method 400 may include an additional operation comprising determining an adjustment for a semiconductor structure (e.g., a metrology target) design. Additionally, the order in which the operations of method 400 are illustrated in FIG. 4 and described herein is not intended to be limiting.

In some embodiments, one or more portions of method 400 may be implemented in and/or controlled by one or more processing devices (e.g., a digital processor, an analog processor, a digital circuit designed to process information, an analog circuit designed to process information, a state machine, and/or other mechanisms for electronically processing information). The one or more processing devices may include one or more devices executing some or all of the operations of method 400 in response to instructions stored electronically on an electronic storage medium. The one or more processing devices may include one or more devices configured through hardware, firmware, and/or software to be specifically designed for execution of one or more of the operations of method 400 (e.g., see discussion related to FIG. 6 below).

At operation 402, an electronic representation (e.g., a model) of the semiconductor structure (e.g., a metrology target) is separated into first and second portions. In some embodiments, the first portion is a top portion of the semiconductor structure, and the second portion is a bottom portion of the semiconductor structure. In some embodiments, the first portion has first repeating structures, and the second portion has second, different repeating structures. The first and second repeating structures may be in an X and/or a Y direction of the semiconductor structure. The first portion (e.g., a top portion) may be separated into first repeating unit cells based on the first repeating structures, and the second (e.g., bottom) portion may be separated into second (different) repeating unit cells based on the second repeating structures.

At operation 404, electromagnetic responses of the first portion and the second portion are separately simulated using a layer based simulation. The layer based simulation comprises or is based on rigorous coupled wave analysis (RCWA). The separate simulations are performed layer by layer, from top to bottom, bottom to top, or from outer layers to inner layers of the first and second portions of the semiconductor structure. Operation 404 may include separately simulating an electromagnetic response of each of the first and second repeating unit cells using the layer based simulation. Separately simulating the electromagnetic response of each of the first and second repeating unit cells using the layer based simulation comprises performing a rigorous coupled wave analysis for each given unit cell and/or other operations.

For example, simulations for operation 404 may utilize a “fast” RCWA method. This RCWA formalism avoids solving the eigen-value problem directly in each layer as in traditional RCWA formalism, which is costly in computation time and sometimes unstable. Instead it converts the problem into a tridiagonal linear system which can be solved efficiently by using techniques like LU decomposition. The structure is first sliced into layers in z axis and the electrical permittivity of a layer is used to build the matrix representing optical property of that layer. The optical response is simulated layer by layer. Only the immediate results that is necessary to construct the reflection coefficient of the full structure to carry to the next layer. This facilitates simulation of reflectivity of the whole semiconductor structure going through the structure layer by layer (e.g., from top and bottom until finally meeting in the middle). With an appropriate choice for a division (or “mid”) point between the first (e.g. top) and second (e.g., bottom) portions both the first and second portions can be further sub-divided into smaller, identical unit cells in X-Y plane. Once this division is complete, separate simulations may be performed using the unit cells (which can then be synthesized as described below). One way to separate the structure involves the input of top unit cell and bottom unit cell pitch. An algorithm examines every layer from top to bottom to verify that the layers contain the periodicity of the top unit cell pitch, stopping where this periodicity no longer exists. The algorithm then starts from bottom layer to examine each layer upward to see if it contains the periodicity of bottom unit cell and stops where this periodicity no longer exists. If the top periodicity and bottom periodicity check meet, the structure is can be separated at the meeting point. If the top periodicity and the bottom periodicity overlaps, then the structure can be separated at any layer that exhibits both periodicity.

At operation 406, the separate simulations of the electromagnetic response of the first portion and the second portion are combined into a combined simulation, where only partial (e.g., reflectivity) portions of scattering matrices determined by the layer based simulation for the separate simulations are combined for the combined simulation. Operation 406 may include combining separate simulations of the first repeating unit cells to generate the simulation of the first portion; and combining separate simulations of the second repeating unit cells to generate the simulation of the second portion, for example. Combining the separate simulations of the first repeating unit cells to generate the simulation of the first portion comprises determining a first layer based intermediate scattering matrix, and combining the separate simulations of the second repeating unit cells to generate the simulation of the second portion comprises determining a second layer based intermediate scattering matrix. The first and second layer based intermediate scattering matrices comprise a top down reflectivity matrix and a (different) bottom up reflectivity matrix, respectively.

Combining the separate simulations of the first portion and the second portion into a combined simulation comprises a rigorous coupled wave analysis based on the first and second layer based intermediate scattering matrices. The rigorous coupled wave analysis based on the first and second layer based intermediate scattering matrices comprises a matrix transformation. Since this combination is mathematically rigorous, the combined simulation is identical to a result obtained by directly applying typical RCWA on a non-unit cell divided semiconductor structure, with computer numeric precision.

As an example of several of these principles, a scattering matrix is a mathematical structure that describes how a beam (typically a plane wave) propagating towards a given semiconductor structure (e.g., a stack) can be related to a set of beams propagating away from the structure, in such a way that the fields inside the stack and the (incident and scattered) fields outside the stack together represent a solution of Maxwell's equations in all space. The scattering matrix can be subdivided into four blocks R, T, R′, T′, as follows:

$$S = [ \begin{matrix}R & {T}^{′} \\ T & {R}^{′}\end{matrix} ]$$

Each of the blocks R, T, R′, T′ represent N×N matrices where N is the total number of channels on each side of the stack. In this example, N=2×(2×Nₕₓ+1)×(2×N_{hy}+1), where Nₕₓ, N_{hy} represent the number of one-sided harmonics in the x and y directions respectively and the prefactor of two comes from the two polarization states per Fourier mode. Specifically, the block R comprises the reflection coefficients; i.e. the scattering amplitudes of beams that propagate downwards onto the stack from above and are reflected back upwards; the block T comprises the transmission coefficients, i.e. the scattering amplitudes of beams coming from above the stack and being transmitted downwards to leave the stack on the other side. Analogously, the block R′ comprises the scattering coefficients of beams that propagate upwards onto the stack from below and are reflected back downwards, and T′ comprises the scattering amplitudes of beams coming from below the stack and being transmitted upwards.

Each block is a matrix containing N×N complex-valued coefficients (describing the scattered phase and amplitude for each combination of an incoming and outgoing channel); every block is, in general, a dense matrix because every incident channel (Fourier mode+polarization) can in principle scatter into every outgoing channel. This includes all the evanescent Fourier modes, because in the case relevant here, the reference plane with respect to which the phases and amplitudes of the scattered beams are computed is taken to be directly above or directly below the stack; the evanescent have not yet “died out” at a finite distance from the stack.

In RCWA, a stack is considered as a set of a (typically large) number of so-called slices, each of which has a finite thickness. Inside each slice the geometry is invariant in z (it has a constant cross-section within its z-range). RCWA can be used to compute a close enough approximation to the scattering matrix for each of these slices in an efficient way given a description of its cross sectional shapes and optical material properties. Different formulations of the RCWA vary in the way in which the scattering matrix of a single slice is computed; these variations are irrelevant to the present discussion. (Notice that a primary reason why “Fast” RCWA is fast, lies in the specific scheme it uses to obtain the approximate scattering matrices per slice.) A list of scattering matrices S₁, S₂ . . . , Sₙ is obtained (where S₁ is the scattering matrix of the topmost slice and Sₙ the scattering matrix of the bottommost slice).

In the most general case, the requested output of the RCWA is the Redheffer product Sₜₒₜₐₗ=S₁*S₂* . . . *Sₙ; i.e. the scattering matrix of the stack as a whole. In practice, only some of the coefficients contained in this matrix are of interest, as described below.

The matrix Sₜₒₜₐₗ contains information on all scattered beams for all possible incident channels (propagating and evanescent; incident from above or from below; reflected and transmitted). In the typical case relevant for scatterometric optical metrology, only the reflection coefficients R of the stack are of interest (i.e., a single one of the four matrix blocks in the scattering matrix). Moreover, only a single incident Fourier mode is typically considered (=two incident channels because of the two incident polarization types) and only a subset of all possible outgoing Fourier modes (namely only the propagating outgoing modes).

Let e_{0,s}=(0, 0, . . . , 0, 1, 0, . . . , 0)^{T} be a unit vector picking out the (0,0)^{th} mode for s polarization and analogously for p polarization. We define an N×2 matrix K=[e_{0,s} e_{0,p}] and let L=[e₁ . . . eₘ] similarly be an N×m matrix consisting of m unit columns which pick out the m relevant outgoing channels. The part of the output of the algorithm we are interested in is just the m×2 elements of the matrix rₜₒₜₐₗ=L^{T}RₜₒₜₐₗK, where Rₜₒₜₐₗ is the upper-left quadrant of Sₜₒₜₐₗ. Two approaches are implemented in RCWA code for computing these coefficients, which each work by iterating over the slices, which are each described below.

In the bottom-up approach, intermediate scattering matrices are defined S_{i,total}=Sᵢ*Sᵢ₊₁* . . . *Sₙ. These intermediate scattering matrices are determined recursively down from i=n to i=1, using the identity S_{i,total}=Sᵢ*S_{i+1,total} and the fact that the Sᵢ represent single-slice scattering matrices which can be computed (or at least, approximated) in closed form. In the end, Sₜₒₜₐₗ=S_{1,total} is returned.

In practice, only the upper-left quadrant Rₜₒₜₐₗ of the total scattering matrix Sₜₒₜₐₗ is of interest. Therefore, it is sufficient to retain only the upper-left quadrant R_{i,total} of the intermediate scattering matrix throughout all the steps of the iteration over the slices i. According to the definition of the Redheffer star product,

$${R}_{i , total} = {R}_{i} + {{T}_{i}^{′} ( I - {R}_{i + 1 , total} {R}_{i}^{′} )}^{- 1} {R}_{i + 1 , total} {T}_{i}$$

Note that the transmission and reflection matrices not labeled “total” refer to just a single slice and can be computed explicitly; they can be discarded after their use in step i of the iteration. After the last step i=1, rₜₒₜₐₗ=L^{T}R_{1,total}K. Notice that R_{i,total} (the only matrix retained in memory and updated through the steps of the iteration) is an N×N matrix.

In the top-down approach, iteration from i=1 up to i=n is performed using the recursion formula S_{i+1,total}=S_{i,total}*Sᵢ₊₁. As in the bottom-up approach, the present method benefits from the fact that only the subset rₜₒₜₐₗ=L^{T}RₜₒₜₐₗK is of interest. However, due to the different recursion order, four matrices need to be kept in memory, namely the N×N matrix

$${R}_{i , total}^{′} , the N \times 2 matrix {t}_{i , total} = {T}_{i , total} K , \\ the m \times N matrix {t}_{i , total}^{′} = {L}^{T} {T}_{i , total}^{′} ,$$

and the m×2 matrix L^{T}R_{1,total}K. From the definition of the Redheffer star product a layer update step can be defined by four recursive expressions:

$${R}_{i + 1 , total}^{′} = {R}_{i + 1}^{′} + {{T}_{i + 1} ( I - {R}_{i , total}^{′} {R}_{i + 1} )}^{- 1} {R}_{i , total}^{′} {T}_{i + 1}^{′} \\ {t}_{i + 1 , total} = {T}_{i + 1} ( I - {R}_{i , total}^{′} {{R}_{i + 1} )}^{- 1} {t}_{i + 1 , total} \\ {t}_{i + 1 , total}^{′} = {{t}_{i , total}^{′} ( I - {R}_{i + 1} {R}_{i , total}^{′} )}^{- 1} {T}_{i + 1}^{′} \\ {r}_{i + 1 , total} = {r}_{i , total} + {{t}_{i , total}^{′} ( I - {R}_{i + 1} {R}_{i + 1 , total}^{′} )}^{- 1} {R}_{i + 1} {t}_{i , total}$$

After the last iteration, the requested subset rₜₒₜₐₗ=r_{N,total} of reflection coefficients is obtained for the total stack.

In existing Fast-RCWA algorithms, there is an implementation of both the bottom-up and top-down algorithms. The bottom up algorithm includes updating a matrix called “Z” throughout the iteration over the layers (from i=n down to i=1). This is an N×N complex-valued matrix. While its definition is not identical to the R_{i,total} as defined above, it has exactly the same dimensions and is used in a similar way (with a set of matrix-vector products and a single LU decomposition per iterative step). In general, it has the same effective information content as R_{i,total}.

Analogously, the top down algorithm may track four complex matrices. These may have matrix sizes of respectively m×N, N×2, m×2, and N×N, and may be analogous (though not exactly identical) to the matrices

$${t}_{i , total}^{′} , {t}_{i , total} , {r}_{i , total} , and {R}_{i , total}^{′}$$

respectively as defined above.

Assume the stack (e.g., semiconductor structure) geometry has a geometry which has a smaller periodicity than the periodicity of the (real-space) unit cell used to define the (reciprocal-space) grid of Fourier modes; in other words, the stack is repeated an integer number of times N_{rep,x}, N_{rep,y} in the x and/or y direction (we take Nᵣₑₚ=1 if there is no repetition in a given direction). Also let pairs of indices (i, j) with i,j∈{1, . . . , N} indicate the elements of the matrices R, T, R′, T′, and let these pairs be associated with 6-tuples

(iₚₒₗ,iₓ,i_{y},jₚₒₗ,jₓ,j_{y}) with iₚₒₗ,jₚₒₗ∈{s,p},iₓ,jₓ∈{−Nₕₓ, . . . , Nₕₓ}, and i_{y},j_{y}∈{−N_{hy}, . . . , N_{hy}}.

It follows from the interpretation of the matrix elements of these matrices as coefficients of an expansion on a basis set of Fourier modes that a matrix element can be non-zero only if iₓ ≡jₓ (mod N_{rep,x}) and i_{y} ≡j_{y} (mod N_{rep,y}). This means that the scattering matrix of the full N-mode grid can be computed by solving (N_{rep,x}N_{rep,y}) sub-problems each of which requires manipulating matrices of size

$$\frac{N}{{N}_{rep , x} {N}_{rep , y}} \times \frac{N}{{N}_{rep , x} {N}_{rep , y}} .$$

Because of the approximately cubic scaling of the RCWA algorithm in the size of a sub-problem, this results in a very significant reduction in the computation time.

Once the full N×N scattering matrix of a repetitive top portion (e.g., grating) A has been computed (all the slices of a top grating), which will have a certain sparsity structure, and also the full N×N scattering matrix of a repetitive bottom portion (e.g., grating) B, which will have a different periodicity and hence also a different sparsity structure, the full scattering matrix can be determined by an application of the general Redheffer star product expression.

The total computation time is thus the time to compute the sparse top matrix and sparse bottom matrix (which should scale approximately linearly in the total number of repetitions N_{rep,x}N_{rep,y} present in a given half-stack) plus the time of the Redheffer product evaluation, which still scales approximately cubically in the total system size N (and hence the number of repetitions). However, the Redheffer star product to obtain the combination of stack A and stack B needs to happen only once, while the (much smaller) Redheffer star product that appears in the iteration over the slices, needs to happen again for each slice, and hence will in practice often dominate the total computation time (which is thus greatly reduced compared to the situation that all Redheffer star products need to be taken on the full set of N channels).

The present systems and methods are configured to combine the bottom-up and top-down approaches in such a way that a semiconductor structure (e.g., a stack) is separated (e.g., through the middle) at layer i and evaluate the topmost i slices using the top-down approach and the bottommost n—i slices using the bottom-up approach. The symbol R_{B}=R_{i,total} is introduced for the output of the bottom-up algorithm (as applied to the bottom slices of the stack) and the symbols

$${R}_{A}^{′} = {R}_{i , total}^{′} , {t}_{A} = {t}_{i , total} , {t}_{A}^{′} = {t}_{i , total}^{′} , and {r}_{A} = {r}_{i , total}$$

for the outputs of the top-down algorithm (as applied to the top slices of the stack).

While these outputs are not enough to obtain the full scattering matrix of the stack Sₜₒₜₐₗ, they are still sufficient to obtain the subset of scattering coefficients we are interested in (namely those in matrix rₜₒₜₐₗ). The following expression can be derived from the general expression of the full Redheffer star product:

$${r}_{total} = {r}_{A} + {{t}_{A}^{′} ( I - {R}_{B} {R}_{A}^{′} )}^{- 1} {R}_{B} {t}_{A}$$

For the multi-pitch case (cDBO top-bottom separation) as one example, the present systems and methods combine the ideas of computing the first (e.g., top) and second (e.g., bottom) portion scattering matrices as a set of smaller scattering problems with the (partial) Redheffer star product on the sub-stacks A and B as defined above. Notice that a final recombination step still requires the multiplication of a set of vectors by a matrix inverse; and the matrix which is inverted is in general a dense N×N matrix (because at this point the lattice symmetries of the top and bottom gratings are mixed).

Thus, as described above, the recombination step (e.g., the combining of separate simulations as described above) can be performed partially to obtain just reflection coefficients, and specifically only the reflection coefficients contained in the m×2 sub-matrix of interest. This is an optimization in itself (during the recombination step) compared to prior methods, but it also facilitates implementation of the scattering problems of the top and bottom gratings of the stack using the “partial” approach implemented in “Fast” RCWA (i.e., computing only R for the TopDown part and only R′, t, t′, and r for the BottomUp part, instead of computing full scattering matrices in every layer: all channels for all four quadrants).

Returning to FIG. 4, at operation 408, an optical property of the semiconductor structure (e.g., metrology target) is determined based on the combined simulation and/or other information. In a typical setting, a set of incident beams representing the illuminating source, the geometry property of the target and material property are the input to the model. Then the model calculates the optical properties using rigorous physics modeling based on Maxwell equations. The optical property comprises a transmissive and/or reflective property of the semiconductor structure. In some embodiments, the optical property comprises a reflection coefficient and/or other optical properties. The optical property may be configured to be provided as input for an overlay and/or alignment simulation as part of a semiconductor manufacturing diffraction based optical metrology process and/or have other uses.

In some embodiments, operation 408 incudes determining a semiconductor structure metrology target design based on the combined simulation and/or the determined optical property. In some embodiments, operation 408 comprises determining an adjustment for a semiconductor structure metrology target design. For example, this may include automatically adjusting, with the one or more processors, a shape and/or location of one or more features of the target design. In some embodiments, operation 408 includes determining a process adjustment for fabricating the metrology target design based on simulation output, determined optical properties, and/or other information. This may be performed by one or more computer systems CS (shown in FIG. 3), a processor described as part of the computer system illustrated in FIG. 6 and described below, and/or other processors.

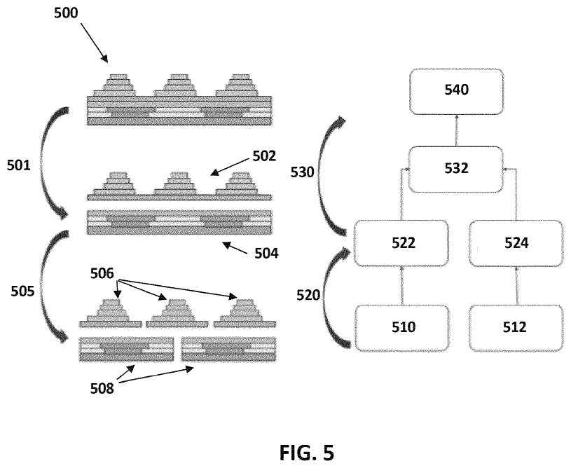

FIG. 5 provides a graphical representation of the exemplary method for simulating an electromagnetic response of a semiconductor structure to determine an optical property of the semiconductor structure for diffraction based optical metrology (e.g., method 400 shown in FIG. 4 and described above). FIG. 5 illustrates a semiconductor structure 500 that is separated 501 into first (e.g., top) and second (e.g., bottom) portions 502 and 504 respectively. First and second portions 502 and 504 are then separated 505 further into first and second repeating unit cells 506 and 508 respectively. Electromagnetic responses of each of the first and second repeating unit cells 506 and 508 are separately simulated 510 and 512 using the layer based simulation (e.g., fast RCWA). Separate simulations 510 of the first repeating unit cells 506 are combined 520 to generate the simulation 522 of first portion 502; and separate simulations 512 of the second repeating unit cells 508 are combined 520 to generate the simulation 524 of second portion 504. Separate simulations 522 and 524 of the electromagnetic response of first portion 502 and second portion 504 are combined 530 into a combined simulation 532, and an optical property 540 is determined based on combined simulation 532.

FIG. 6 is a diagram of an example computer system CS (which may be similar to or the same as CS shown in FIG. 3) that may be used for one or more of the operations described herein. Computer system CS includes a bus BS or other communication mechanism for communicating information, and a processor PRO (or multiple processors) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, portions of one or more operations described herein may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” or a “machine readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have (machine-readable) instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more machine-readable instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic, or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic, or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, or stored in storage device SD, or other non-volatile storage for later execution. In this manner, computer system CS may obtain application code in the form of a carrier wave.

The concepts disclosed herein may be used with any imaging, etching, polishing, inspection, etc. system for sub wavelength features, and may be useful with emerging imaging technologies capable of producing increasingly shorter wavelengths. Emerging technologies include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

Embodiments of the present disclosure can be further described by the following clauses.

1. A computer implemented method for simulating an electromagnetic response of a semiconductor structure to determine an optical property of the semiconductor structure for diffraction based optical metrology, the method comprising:
separating an electronic representation of the semiconductor structure into first and second portions;
separately simulating an electromagnetic response of the first portion and the second portion using a layer based simulation;
combining separate simulations of the electromagnetic response of the first portion and the second portion into a combined simulation, wherein only partial portions of scattering matrices determined by the layer based simulation for the separate simulations are combined for the combined simulation of the electromagnetic response such that the combined simulation comprises only the partial portions; and
determining the optical property based on the combined simulation of the electromagnetic response.
   2. The method of clause 1, wherein the layer based simulation comprises or is based on rigorous coupled wave analysis (RCWA), and wherein the separate simulations are performed layer by layer, from top to bottom, bottom to top, or from outer layers to inner layers of the first and second portions of the semiconductor structure.
   3. The method of clause 1 or 2, wherein the optical property comprises a transmissive and/or reflective property of the semiconductor structure in response to incident radiation.
   4. The method of clause 3, wherein the optical property comprises a reflection coefficient.
   5. The method of any of clauses 1-4, wherein the first portion has first repeating structures, and the second portion has second, different repeating structures.
   6. The method of clause 5, wherein the first and second repeating structures are in an X and/or a Y direction of the semiconductor structure, the first portion is a top portion of the semiconductor structure, and the second portion is a bottom portion of the semiconductor structure.
   7. The method of clause 5 or 6, further comprising:
separating the first portion into first repeating unit cells based on the first repeating structures,
separating the second portion into second repeating unit cells based on the second repeating structures,
separately simulating an electromagnetic response of each of the first and second repeating unit cells using the layer based simulation;
combining separate simulations of the first repeating unit cells to generate the simulation of the first portion; and
combining separate simulations of the second repeating unit cells to generate the simulation of the second portion.
   8. The method of clause 7, wherein separately simulating the electromagnetic response of each of the first and second repeating unit cells using the layer based simulation comprises performing a rigorous coupled wave analysis for each given unit cell.
   9. The method of clause 7 or 8, wherein combining the separate simulations of the first repeating unit cells to generate the simulation of the first portion comprises determining a first layer based intermediate scattering matrix, and combining the separate simulations of the second repeating unit cells to generate the simulation of the second portion comprises determining a second layer based intermediate scattering matrix.
   10. The method of clause 9, wherein the first and second layer based intermediate scattering matrices comprise a top down reflectivity matrix and a bottom up reflectivity matrix, respectively.
   11. The method of clauses 9 or 10, wherein the first and second layer based intermediate scattering matrices are different.
   12. The method of any of clauses 9-11, wherein combining the separate simulations of the first portion and the second portion into a combined simulation comprises a rigorous coupled wave analysis based on the first and second layer based intermediate scattering matrices.
   13. The method of clause 12, wherein the rigorous coupled wave analysis based on the first and second layer based intermediate scattering matrices comprises a matrix transformation.
   14. The method of any of clauses 1-13, wherein the electronic representation of the semiconductor structure is determined based on a design layout of a semiconductor device.
   15. The method of any of clauses 1-14, wherein the semiconductor structure comprises a semiconductor metrology target for diffraction based optical metrology.
   16. The method of clause 15, wherein the metrology target comprises a grating.
   17. The method of any of clauses 1-16, wherein the optical property is configured to be provided as input for an overlay and/or alignment simulation as part of a semiconductor manufacturing process.
   18. The method of any of clauses 1-17, further comprising determining a semiconductor structure metrology target design based on the combined simulation and/or the determined optical property.
   19. The method of any of clauses 1-18, wherein the partial portions of scattering matrices comprise reflectivity portions.
   20. A non-transitory computer readable medium having instructions thereon, the instructions when executed by a computer causing the computer to perform the method of any of clauses 1-19.
   21. A system comprising one or more processors configured by machine readable instructions to perform the method of any of clauses 1-19.

While the concepts disclosed herein may be used for manufacturing with a substrate such as a silicon wafer, it shall be understood that the disclosed concepts may be used with any type of manufacturing system (e.g., those used for manufacturing on substrates other than silicon wafers).

In addition, the combination and sub-combinations of disclosed elements may comprise separate embodiments. For example, one or more of the operations described above may be included in separate embodiments, or they may be included together in the same embodiment.

The descriptions above are intended to be illustrative, not limiting. Thus, it will be apparent to one skilled in the art that modifications may be made as described without departing from the scope of the claims set out below.

1. A method comprising:
separating an electronic representation of a semiconductor structure into first and second portions;
separately simulating, by a hardware computer system, an electromagnetic response of the first portion and the second portion using a layer based simulation;
combining separate simulations of the electromagnetic response of the first portion and the second portion into a combined simulation, wherein only partial portions of scattering matrices determined by the layer based simulation for the separate simulations are combined for the combined simulation of the electromagnetic response such that the combined simulation comprises only the partial portions; and
determining an optical property of the semiconductor structure based on the combined simulation of the electromagnetic response.

2. The method of claim 1, wherein the layer based simulation comprises or is based on rigorous coupled wave analysis (RCWA), and wherein the separate simulations are performed layer by layer, from top to bottom, bottom to top, or from outer layers to inner layers of the first and second portions of the semiconductor structure.

3. The method of claim 1, wherein the optical property comprises a transmissive and/or reflective property of the semiconductor structure in response to incident radiation.

4. The method of claim 3, wherein the optical property comprises a reflection coefficient.

5. The method of claim 1, wherein the first portion has first repeating structures, and the second portion has second, different repeating structures.

6. The method of claim 5, wherein the first and second repeating structures are in an X and/or a Y direction of the semiconductor structure, the first portion is a top portion of the semiconductor structure, and the second portion is a bottom portion of the semiconductor structure.

7. The method of claim 5, further comprising:
separating the first portion into first repeating unit cells based on the first repeating structures,
separating the second portion into second repeating unit cells based on the second repeating structures,
separately simulating an electromagnetic response of each of the first and second repeating unit cells using the layer based simulation;
combining separate simulations of the first repeating unit cells to generate the simulation of the first portion; and
combining separate simulations of the second repeating unit cells to generate the simulation of the second portion.

8. The method of claim 7, wherein separately simulating the electromagnetic response of each of the first and second repeating unit cells using the layer based simulation comprises performing a rigorous coupled wave analysis for each given unit cell.

9. The method of claim 7, wherein combining the separate simulations of the first repeating unit cells to generate the simulation of the first portion comprises determining a first layer based intermediate scattering matrix, and combining the separate simulations of the second repeating unit cells to generate the simulation of the second portion comprises determining a second layer based intermediate scattering matrix.

10. The method of claim 9, wherein the first and second layer based intermediate scattering matrices comprise a top down reflectivity matrix and a bottom up reflectivity matrix, respectively, and wherein the first and second layer based intermediate scattering matrices are different.

11. The method of claim 9, wherein combining the separate simulations of the first portion and the second portion into a combined simulation comprises a rigorous coupled wave analysis based on the first and second layer based intermediate scattering matrices, and
wherein the rigorous coupled wave analysis based on the first and second layer based intermediate scattering matrices comprises a matrix transformation.

12. The method of claim 1, wherein the electronic representation of the semiconductor structure is determined based on a design layout of a semiconductor device, wherein the semiconductor structure comprises a semiconductor metrology target for diffraction based optical metrology, and wherein the metrology target comprises a grating.

13. The method of claim 1, wherein the optical property is configured to be provided as input for an overlay and/or alignment simulation as part of a semiconductor manufacturing process.

14. The method of claim 1, further comprising determining a semiconductor structure metrology target design based on the combined simulation and/or the determined optical property.

15. The method of claim 1, wherein the partial portions of scattering matrices comprise reflectivity portions.

16. A non-transitory computer-readable medium comprising instructions stored therein or thereon, the instructions, when executed by a computer system, are configured to cause the computer system to at least:
separate an electronic representation of a semiconductor structure into first and second portions;
separately simulate an electromagnetic response of the first portion and the second portion using a layer based simulation;
combine separate simulations of the electromagnetic response of the first portion and the second portion into a combined simulation, wherein only partial portions of scattering matrices determined by the layer based simulation for the separate simulations are combined for the combined simulation of the electromagnetic response such that the combined simulation comprises only the partial portions; and
determine an optical property of the semiconductor structure based on the combined simulation of the electromagnetic response.

17. The computer-readable medium of claim 16, wherein the layer based simulation comprises or is based on rigorous coupled wave analysis (RCWA), and wherein the separate simulations are performed layer by layer, from top to bottom, bottom to top, or from outer layers to inner layers of the first and second portions of the semiconductor structure.

18. The computer-readable medium of claim 16, wherein the optical property comprises a transmissive and/or reflective property of the semiconductor structure in response to incident radiation.

19. The computer-readable medium of claim 16, wherein the instructions are further configured to cause the computer system to:
separate the first portion into first repeating unit cells based on first repeating structures of the first portion,
separate the second portion into second repeating unit cells based on second repeating structures of the second portion, the second repeating structures different than the first repeating structures,
separately simulate an electromagnetic response of each of the first and second repeating unit cells using the layer based simulation;
combine separate simulations of the first repeating unit cells to generate the simulation of the first portion; and
combine separate simulations of the second repeating unit cells to generate the simulation of the second portion.

20. The computer-readable medium of claim 16, wherein the electronic representation of the semiconductor structure is determined based on a design layout of a semiconductor device, wherein the semiconductor structure comprises a semiconductor metrology target for diffraction based optical metrology, and wherein the metrology target comprises a grating.
